(19) United States
(12) Patent Application Publication
(10) Pub. No.: US 2015/0123105 A1
(43) Pub. Date: May 7, 2015

(54) OFF-CENTER SPIN-COATING AND SPIN-COATED APPARATUSES

(71) Applicants: The Board of Trustees of the Leland Stanford Junior University, Palo Alto, CA (US); Board of Regents of the University of Nebraska, Lincoln, NE (US)

(72) Inventors: Zhenan Bao, Stanford, CA (US); Gaurav Giri, Cambridge, MA (US); Yongbo Yuan, Lincoln, NE (US); Jinsong Huang, Lincoln, NE (US)

(21) Appl. No.: 14/531,401

(22) Filed: Nov. 3, 2014

Related U.S. Application Data
(60) Provisional application No. 61/898,547, filed on Nov. 1, 2013.

(51) Int. Cl. H01L 51/00; B05C 11/08

(52) U.S. Cl. CPC H01L 51/0003; H01L 51/0074; B05C 11/08; H01L 51/0545
USPC 257/40; 438/99; 118/52

(57) ABSTRACT

Various aspects of the instant disclosure are directed to methods and to apparatuses involving spin-coating and spin-coated materials. As may be implemented in connection with one or more embodiments, a solution having objects dispersed therein is applied to a substrate and the substrate is spun about an axis that is off-center relative to a center of the substrate. The objects are thus aligned along a predominantly unidirectional orientation. The solution is solidified with the objects aligned to one another along the predominantly unidirectional orientation.

### FEDERALLY-SPONSORED RESEARCH AND DEVELOPMENT

This invention was made with Government support under contract W31P4Q-08-C-0439 awarded by the Defense Advanced Research Projects Agency. The Government has certain rights in the invention.

### BACKGROUND

A variety of materials are usefully provided in a film-type arrangement, for use in many different types of applications. For instance, organic materials are used in electronic applications, such as transparent organic semiconductor films that can be used in flat-panel displays, radio-frequency identification tags, complementary integrated circuits and biological and medical applications.

For organic semiconductor films, carrier mobility can be important for providing desirable conductivity behavior. However, carrier mobility can be influenced by the crystallinity, molecular packing structures of the organic thin films, and charge traps at the gate dielectric/semiconductor interface. Due to small van der Waals interaction between organic molecules, the crystallinity, grain size and crystal alignment of solution-processed organic thin films can be sensitive to fabrication conditions, such as solvent evaporation rate and liquid surface tension force. In addition to the changed thin film morphology, certain molecular organic semiconductors can form various molecular packing structures (polymorphs) by changing film formation processes. Since the electronic wavefunction overlap that determines the charge transfer integral is a very sensitive function of the precise molecular packing, the various polymorphs generally have different carrier mobilities with some having a higher mobility than their equilibrium structures.

These and other aspects have presented challenges to the implementation of objects such as organic materials and nanomaterials in films, for a variety of applications.

### SUMMARY

Various example embodiments are directed to film-based materials, apparatuses and their implementation.

According to an example embodiment, a solution having objects dispersed therein is applied to a substrate. The solution is spun about an axis that is off-center, relative to a center of the substrate, to align the objects along a predominantly unidirectional orientation. The solution is solidified with the objects aligned to one another and along the predominantly unidirectional orientation.

According to another embodiment, an apparatus or method is directed to an organic semiconductor and a polymer that are cooperatively configured and arranged in a film. The film has a predominant degree of transparency and a mobility sufficient to provide charge carrier flow in response to an electric field at the degree of transparency.

Another embodiment is directed to an apparatus or method involving such an organic semiconductor and polymer in which the mobility is based upon one or more of metastable crystalline structure, a blend of the polymer and organic semiconductor, and an off-center spin-coating (OCSC) approach.

Another embodiment is directed to a spin-coated apparatus having an organic semiconductor and a polymer cooperatively arranged with the organic semiconductor in a film on a substrate. The film has a predominant degree of transparency, and a mobility sufficient to provide charge carrier flow in response to an electric field at the degree of transparency. The polymer has predominantly aligned molecules with a unidirectional crystalline orientation and a mobility, with the organic semiconductor, that is greater than 33 cm²/Vs and less than about 150 cm²/Vs.

Another embodiment is directed to an apparatus having a spin-coating platform that rotates about an axis, a substrate on the spin-coating platform and offset from the axis, and a film on the substrate. The film includes objects dispersed therein, with the objects being aligned to one another along a predominantly unidirectional orientation along a direction that extends from the axis and through the film. In some implementations, the spin-coating platform and substrate are arranged with a distance between the axis and substrate that aligns the objects along the predominantly unidirectional orientation by imparting a predominantly unidirectional centrifugal force to the film.

The above discussion/overview is not intended to describe each embodiment or every implementation of the present disclosure. The figures and detailed description that follow also exemplify various embodiments.

### DESCRIPTION OF THE FIGURES

Various example embodiments may be more completely understood in consideration of the following detailed description in connection with the accompanying drawings, in which:

FIG. 1 shows an apparatus, as may be implemented in accordance with one or more embodiments;

FIG. 2 shows an apparatus and approach to spin-coating, in accordance with another example embodiment; and

FIG. 3 shows a structure with aligned objects and a corresponding plot, in accordance with another example embodiment.

While various embodiments discussed herein are amenable to modifications and alternative forms, aspects thereof have been shown by way of example in the drawings and will be described in detail. It should be understood, however, that the intention is not to limit the invention to the particular embodiments described. On the contrary, the intention is to cover all modifications, equivalents, and alternatives falling within the scope of the disclosure including aspects defined in the claims. In addition, the term “example” as used throughout this application is only by way of illustration, and not limitation.

### DETAILED DESCRIPTION

Aspects of the present disclosure are believed to be applicable to a variety of different types of apparatuses, systems and methods involving spin-coatings. While not necessarily so limited, various aspects may be appreciated through a discussion of examples using this context.

Various embodiments are directed to off-center spin-coated films and those films formed in this regard. Such films exhibit an alignment of objects therein, as imparted via centrifugal forces applied via the off-center spin-coating and further as aligned across the coating in a generally common direction. For instance, by offsetting an entire substrate at a distance away from an axis of rotation, the centrifugal force can be aligned across an entire solution on the substrate, which can be used to solidify a film in which the objects are aligned.

One such spin-coating approach involves applying solution having objects such as molecules or nanoparticles therein to a substrate, and spinning the substrate about an axis that is off-center relative to a center of the substrate. This approach may be facilitated, for example, by placing the substrate on platform at a portion thereof that is offset from an axis about which the platform rotates. This approach can be used to align the objects along a predominantly unidirectional orientation. Once aligned, the solution is solidified to form a film having the objects aligned to one another along the predominantly unidirectional orientation. This solidification may be enhanced, for example, via centrifugal forces and air/gas movement about the substrate during spinning.

In connection with one or more such off-center alignment embodiments, it has been discovered that the resulting films exhibit desirable characteristics. For example, it has been discovered that organic materials dispersed in a solution and formed into a film via an OCSC approach exhibit various desirable characteristics. In certain embodiments, these characteristics include one or more of high mobility, transparency, and flexibility.

Various example embodiments are directed to enhancing hole and/or electron mobility in organic materials, implementing spin-coatings as discussed herein. Such embodiments may be implemented in organic materials and organic electronics, such as in an organic field effect transistor (OFET) device, displays, logic circuits, sensors, memory, transparent circuits (e.g., circuits with a degree of transparency, such as at least 50%), flexible devices, polarizing components such as films, and large scale electronics.

As further characterized herein, one or more embodiments may also be implemented in connection with embodiments disclosed in the underlying U.S. Provisional Patent Application Ser. No. 61/898,547, to which benefit is claimed and which is fully incorporated herein by reference. For instance, various characterizations of the resulting films as noted in the plots and other figures in the Appendices that form part of the underlying provisional application, may be implemented with films as characterized herein to achieve benefits or other aspects of the film.

In accordance with one or more embodiments, an OCSC approach is used to generate a large centrifugal force via rotation to influence the formation process of a solid film, or change the structure of an existing film. This centrifugal force may be many times the force of gravity. The centrifugal force can be applied to a substrate (or major working area) that is locally away from a center of the rotation, so that every or nearly every region on the substrate (or major working area) is imparted with a centrifugal force with about same direction (e.g., within a few degrees). The substrate can be placed in a variety of postures, such as facing along or opposite to a radial direction of spin-coating, perpendicular or parallel to the radial direction, or at an angle relative thereto. The OCSC can be applied to form a solid film from a liquid phase, or to treat a film by imparting structural change via centrifugal forces applied during the off-center spin-coating treatment.

Locating a film and/or a substrate on which a film is provided in an off-center position relative to a spin-coating access may, for example, involve a 2-4 cm offset from the axis for a ˜4 cm square substrate, or otherwise as a distance of half or more of the width of the substrate.

Such a spinning approach may be implemented by increasing revolutions per minute (RPM) over time to ramp up the rotational speed and related centrifugal force. In one implementation, the RPM is linearly increased from 0 RPM to nearly 1000 RPM (e.g., over about 80 seconds), then at a higher rate of increase to nearly 3000 RPM (e.g., over about 25 seconds) and holding the RPM (e.g., for about 20 seconds) before slowing the rotation to a stop.

A variety of objects are aligned via OCSC embodiments as described herein. Such an object may, for example, include organic particles or molecules and such molecules that may be semiconducting. For instance, small molecules such as TIPS-pentacene (6,13-Bis(triisopropylsilylethynyl)pentacene), DiF-TES-AdT (2,8-difluoro 5,11-triethylsilylethynyl anthradithiophene), 2,7-dialkyl[l]benzothieno[3,2-b][1]benzothiophenes (Cn-BTBT) (e.g., C8-BTBT), and dinaphtho[2,3-b:2′3′-f]-thieno[3,2-b]thiophene (DNTT) derivatives, such as C10-DNTT can be aligned in a film. One or more polymers may be formed in a film, such as P3AT (poly 3-alkylthiophene), PBTTT (poly(2,5-bis(3-tetradecylthiophene-2-yl)thieno[3,2-b]thiophene) and PiI2T-Si (Polyisoindigobithiophene-siloxane), or blends of small molecules and polymers such as TIPS-pentacene/PTAA, and C8-BTBT/P3HT. Nanowires are formed in films in certain embodiments, and may include inorganics such as zinc oxide, silicon and silver, Carbon Nanotubes and Polymeric molecules such as P3HT. Some embodiments involve nanoparticles, such as colloids (e.g., Silica Spheres), Quantum Dots (e.g., lead sulfide and/or cadmium selenide), asymmetric nanoparticles and nanorods (e.g., gold, silver, cadmium selenide and indium phosphide (InP)). Certain embodiments involve submicro- and micro-objects such as fibers (e.g., carbon fibers and/or polyvinylidene fluoride (PVDF) fibers), insulating spheres (e.g., polystyrene (PS) spheres or silica/glass spheres), fluorescence spheres and magnetic spheres. Self-assembling molecules such as phenyltriethoxysilane (PETS), N-octadecyltrichlorosilane (OTS) and 3-aminopropyltriethoxysilane (APS) are used in other embodiments. Further, two or more of these objects may be formed together in such a spin-coated film.

Many variations to an OCSC approach as provided herein are made, in accordance with various embodiments. In some embodiments, a substrate is spun about an axis that is sufficiently distant from the substrate to apply a centrifugal force to the substrate that is aligned across the substrate (e.g., to align objects within about 10 degrees of a direction extending from an of rotation axis and through a center of the film and/or substrate on which the film is formed). Such an approach may involve separating the substrate from the axis by a few centimeters or otherwise at a distance that is up to or exceeding a length or width of the substrate. The centrifugal force can thus be used to align objects, such as to stack particles in a periodic structure. In some implementations, the substrate is spun to apply a centrifugal force across the substrate that is about 100 times the force of gravity, and to thin the substrate to a thickness of less than about three monolayers of molecules in the solution.

In a more particular embodiment, the solution is manipulated via centrifugal force applied by spinning, with a thicker region of the solution having a meniscus front at an outermost portion of the substrate relative to the axis, and with a thinner region of the solution at an innermost portion of the substrate relative to the axis. Solidifying the solution in this regard includes initiating solidification of the solution at the innermost portion of the substrate while evaporating solvent from the solution, and propagating a solidification front of the solution from the innermost portion of the substrate toward the outermost portion of the substrate.

The solution may be solidified in a variety of manners, to suit various embodiments. In some embodiments, the solution is solidified to form a predominantly transparent film, such as to provide a film having a mobility sufficient to provide charge carrier flow in response to an electric field at the degree of transparency. In some implementations, a blend including a polymer and an organic semiconductor is applied to the substrate, and molecules of the polymer are aligned in the predominantly unidirectional orientation. The blend may, for example, be crystallized in the unidirectional orientation.

Another embodiment is directed to a spin-coated apparatus having an organic semiconductor and a polymer cooperatively arranged with the organic semiconductor in a film on a substrate (e.g., an organic polymer blended with PS). The film has a predominant degree of transparency (i.e., passes over 50% of incident light) and a mobility that provides charge carrier flow in response to an electric field at the degree of transparency. Carrier flow in this context may involve, for example, operation as an electrode for a display or touch screen, or for a solar cell application. The polymer exhibits predominantly aligned molecules having a unidirectional crystalline orientation and a mobility with the organic semiconductor that is greater than 33 cm²/Vs and less than about 150 cm²/Vs.

These film characteristics may, for example be imparted via an off-center spin-coating approach as described above, which may impart the mobility characteristics (e.g., consistent with the recognition/discovery noted above). For instance, in some embodiments the aligned unidirectional molecules exhibit characteristics of a spin-coated film applied with an OCSC approach, involving spinning about an axis of rotation that is offset relative to the substrate. This spinning provides the unidirectional alignment via centrifugal forces aligned across the substrate. In certain implementations, the film exhibits off-center spin-coating characteristics that are devoid of microflow, concentration gradients, nucleation and crystal growth kinetics exhibited by blade coating of the film. It has further been discovered that such mobility characteristics can be further enhanced via a combination of two or more components, such as by blending C8-BTBT with PS, or other components as noted above.

In some embodiments, the film in the spin-coated apparatus is in a partially-crystallized state in which a portion of the film closest to the axis is solidified, and a portion of the film furthest from the axis is in a liquid state. The liquid portion of the film exhibits a meniscus region having a thickness that is greater than a thickness of the solidified portion of the film, with the film having a surface that tapers from the meniscus region to the solidified portion of the film. In some instances, the solidified portion exhibits a concentration gradient set via rapid evaporation of solvent from the film and increased viscosity at the portion of the film closest to the axis as incurred via spin-coating (e.g., due to rapid air/gas interaction with the film and stretching along a thinned portion of the film as resulting from via high-speed spinning).

In the context of various embodiments, nucleation and crystal growth kinetics achieved with off-center spin-coating may involve providing a taper-off region at a meniscus front as noted above, having a shape that results from a withdraw effect by the solution and a pull effect by the solidified film with related surface tension characteristics (e.g., which may be effected via the centrifugal force relative, for instance, to a blade coating approach). Via the off-center spin-coating, the withdraw effect caused by the solution is largely due to the centrifugal force applied during the rotation, which can provide a thin taper-off region and small contacting angle.

Further, continual air flow across the solution in spin-coating can enhance the evaporation of solvent from the film, which can lead to a large concentration gradient. The impact of the solvent evaporation rate on the concentration gradient may be more evident at the taper-off region due to thinning of the liquid film at the taper-off region, and slower mass redistribution (diffusion) at the edge relative to bulk portions of the solution due to higher viscosity. Where crystallization is part of a solidification of the film, crystals form at the taper-off region and the air flow thereat (caused by the rotation) sets nucleation and crystal growth kinetics, which finally give a different crystal film (e.g., relative to crystallization carried out without such air flow). In various contexts, such off-center spin-coating may thus impart a crystallized film having a structure characterized as: high crystallinity, compact crystal structure (e.g., via reduced intermolecular spacing), and a highly-aligned crystalline film, the latter two being implemented via large centrifugal forces and surface tension drawing effects. The high crystallinity may be achieved using a high solvent evaporation rate that accelerates the crystal formation speed by forming a higher concentration gradient at the meniscus front, which helps to form high crystalline film with very few amorphous phases.

In some embodiments, an apparatus or method involves an organic semiconductor and a polymer that are cooperatively configured and arranged in a film having a predominant degree of transparency, and a mobility that provides charge carrier flow in response to an electric field at the degree of transparency. Such a blend of the organic semiconductor and polymer may, for example, provide mobility that is greater than about 31.3 cm²/Vs, or greater than 33 cm²/Vs, or higher mobilities such as about 43 cm²/Vs and in some instances, 90-118 cm²/Vs. These respective mobilities can be provided at degrees of transparency of at least 50%, or of up to about 95%, by way of example. In some embodiments, the apparatus is configured with the mobility via one or more of a meta-stable crystalline structure, a reduced lattice spacing, high degree of crystal alignment, mitigated grain mismatch, a polymer/organic semiconductor blend, mitigated surface traps via polymer vertical phase separation and passivation, high solution viscosity and OCSC. In these contexts, a meta-stable crystalline structure may exhibit a film that is unchanged after being stored at room temperature for more than one month, or after annealing at temperatures below 80° C. for three hours.

Another embodiment is directed to an apparatus or method involving an organic semiconductor and a polymer in a film having a predominant degree of transparency and a mobility that is enhanced/provided via one or more of a meta-stable crystalline structure, a polymer/organic semiconductor blend and OCSC. In some embodiments, the mobility greater than about 33 cm²/Vs, or about 118 cm2/Vs.

Another embodiment is directed to an organic electronic component having a mobility higher than 33 cm²/Vs, as provided via one or more of a meta-stable crystalline structure, a polymer/organic semiconductor blend, OCSC method, thin-film thickness, single-crystalline characteristics, high degree of organic crystal alignment, and a polymer segregation into a dielectric interface.

Various apparatuses or methods characterized herein may be implemented in and/or in the manufacture or use of a variety of devices. For instance, various embodiments are directed to one or more of a display, a logic circuit, a sensor, a memory circuit, a transparent or semi-transparent film, a transistor, a flexible device, and a polarizing medium, an organic material, organic electronics, an organic field effect transistor (OFET), a flexible device.

A variety of characteristics may be set to achieve desired mobility. For instance, an organic polymer may be configured with a mobility that is set and/or controlled based on one or more of a meta-stable crystalline structure, a reduced lattice spacing, high degree of crystal alignment, mitigated grain mismatch, a polymer/organic semiconductor blend, mitigated surface traps via polymer vertical phase separation and passivation, and OCSC. In some embodiments, it has been discovered that one or more of these aspects may be implemented to achieve a mobility increase to about 25 cm²/Vs. For instance, such mobility aspects are achieved via the addition of about 5% PS to an organic material blend.

Various aspects are directed to and/or involve a meta-stable crystal polymorph of a small molecular organic semiconductor to realize OFETs with ultra-high mobility, such as mobility greater than about 33 cm²/Vs and up to about 118 cm²/Vs. The carrier mobility may be implemented using meta-stable molecular packing, in which the equilibrium crystal state does not always correspond to a largest mobility, exploiting a meta-stable molecular packing structure to obtain carrier mobility.

In various embodiments, increases in mobility from 14 cm²/Vs to 25 cm²/Vs are effected using a combination of PS passivation and the formation of a continuous C8-BTBT film, as may be implemented via polymer/organic semiconductor blends. The OCSC C8-BTBT films without PS are less continuous than those with PS in the dimension comparable to the device channel length (e.g., due to cracks), which can result in low mobility. Meta-stable packing with slightly reduced molecular spacing can enhance mobility, as consistent with Table Si in Appendix B of the underlying provisional application. The presence of meta-stable packing is indicated by the peak shift in GIXD and the relaxation of the peak and shifting of the absorption spectrum to the equilibrium phase features.

Where a C8-BTBT film is crystallized, such films have been noted to grow along the (010) direction of the C8-BTBT crystal. A highly crystalline structure may exhibit an 18^{th} order out-of-plane (110 Bragg peak for such an off-center spin-coated thin film (e.g., 10-20 nm thick), with in-plane coherence length exhibiting a lower bound crystallite size of about 100 nm. The film exhibits an asymmetric pattern via strong in-plane alignment, with a crystal packing structure being characterized by an additional diffraction peak near the (002) Bragg reflection, with a higher Q_{z}˜0.46 Å⁻¹ characterizing a specific (off-center spin-coated) polymorph. The (11L) Bragg peaks exhibit a shift in position after thermal annealing from Q_{xy}=1.34 Å⁻¹ (meta-stable) to 1.32 Å⁻¹ (equilibrium), characterizing a small intermolecular spacing along a (110) direction in a meta-stable phase. These characteristics are provided, in various embodiments, along with mobilities that facilitate operation as an electrical component such as a transistor as characterized herein.

Various embodiments are directed to OCSC C8-BTBT:PS films having a high hole mobility of 43 cm²/Vs with a transparency greater than 90% in the visible range. The OCSC films can be made desirably thin, maintain structural integrity up to 80° C., and exhibit stability under both DC and AC bias at room temperature. Such mobility can be obtained via highly aligned crystalline grains with a slightly reduced in-plane intermolecular spacing, and via PS blending via the formation of vertical phase separation in which the PS segregates to a dielectric/semiconductor interface. Such an approach may reduce interfacial traps.

Various embodiments are directed to the implementation of an OCSC approach, which can be used to align molecules in one direction (e.g., for polarization). Such an approach can be used in setting a molecular absorption direction, and change polarization of light passing through the film. In some embodiments, such a film is combined with another polarizer to change the angle from which a display may be viewed. In some implementations, a transistor is used to implement polarization in this regard.

In a more specific embodiment, a highly aligned meta-stable structure of C8-BTBT is formed from a blended solution of C8-BTBT and PS by using an OCSC method. Combined with a vertical phase separation of the blend, the highly aligned, meta-stable C8-BTBT films are provided with a significantly increased mobility, as may be implemented for a thin film transistor (TFT) (e.g., up to 43 cm²/Vs (25 cm²/Vs on average)). In some implementations, resulting transistors are formed with a high transparency (e.g., greater than about 90% over the visible spectrum), which may be implemented with high performance organic electronics.

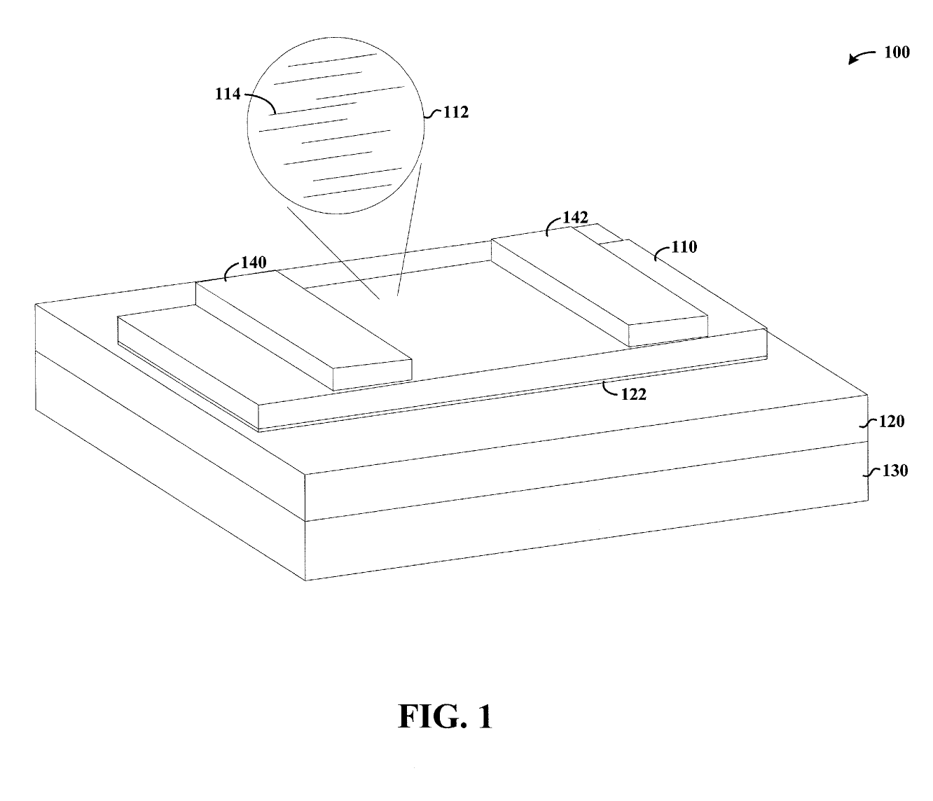

Turning now to the Figures, FIG. 1 shows an apparatus 100, as may be implemented in accordance with one or more embodiments. The apparatus 100 includes a film 110 formed on an underlying substrate, which may be implemented with multiple layers 120 and 130 as shown. For instance, the apparatus 100 may be implemented as a bottom-gate top-contact organic thin film transistor (OTFT) structure, with a cross linked poly(4-vinylphenol): 4,4′-(hexafluoroisopropylidene)diphthalic anhydride (PVP:HDA) dielectric on indium tin oxide (ITO)). A dielectric-type or other layer 122 may also be implemented as shown, as may electrodes 140 and 142 for passing current via the film 110. In some implementations, layer 122 is a PS layer, where the film 110 includes a C8-BTBT material as noted above (e.g., with a vertical phase separation with the PS layer relative to the C8-BTBT, in which the PS layer may mitigate interface traps). As shown in the inset 112, objects 114 such as molecules in the film 110 are aligned along a direction in which a spin-coating approach has provided large centrifugal forces.

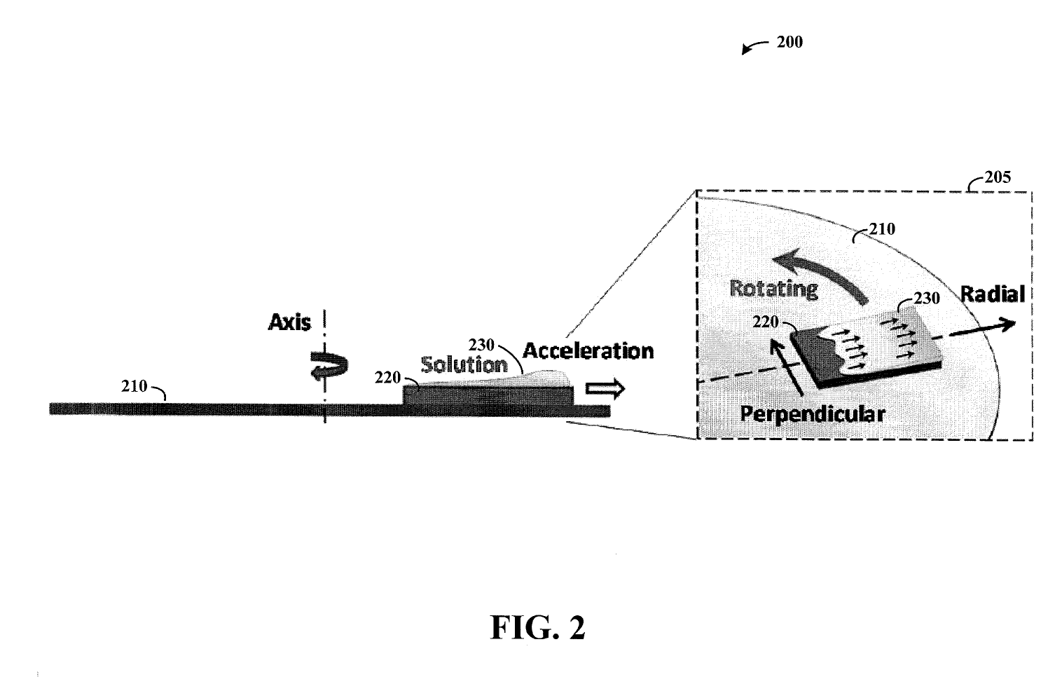

FIG. 2 shows an apparatus 200 and approach to spin-coating, in accordance with another example embodiment. The apparatus 200 includes a spin-coating platform 210 that rotates about an axis as shown. A substrate 220 is on the spin-coating platform and offset from the axis, and a film 230 is on the substrate. The film 230 has objects dispersed therein, and are aligned to one another along a predominantly unidirectional orientation as noted in the inset 205 and depicted by arrows in the film. This direction extends from the axis and through the film 230. The distance between the substrate 220 and the axis is shown by way of example, and can be offset in a variety of manners that facilitate the alignment.

In various embodiments, a semiconductor channel layer is deposited by an OCSC approach such as shown in FIG. 2, in which a substrate is placed away from the center of a spin-coater. Such an approach may involve use of a blend of C8-BTBT with an insulating PS. Utilizing large band gaps exhibited by these organic materials, the resulting films (e.g., when cast on ITO substrates) are formed with a transparency of greater than about 90% in the visible region, such as shown in FIG. 1c of Appendix A in the underlying provisional application. Such highly transparent films may be used in transistors for a variety of devices, such as in flat-panel display backplane and sensor array applications.

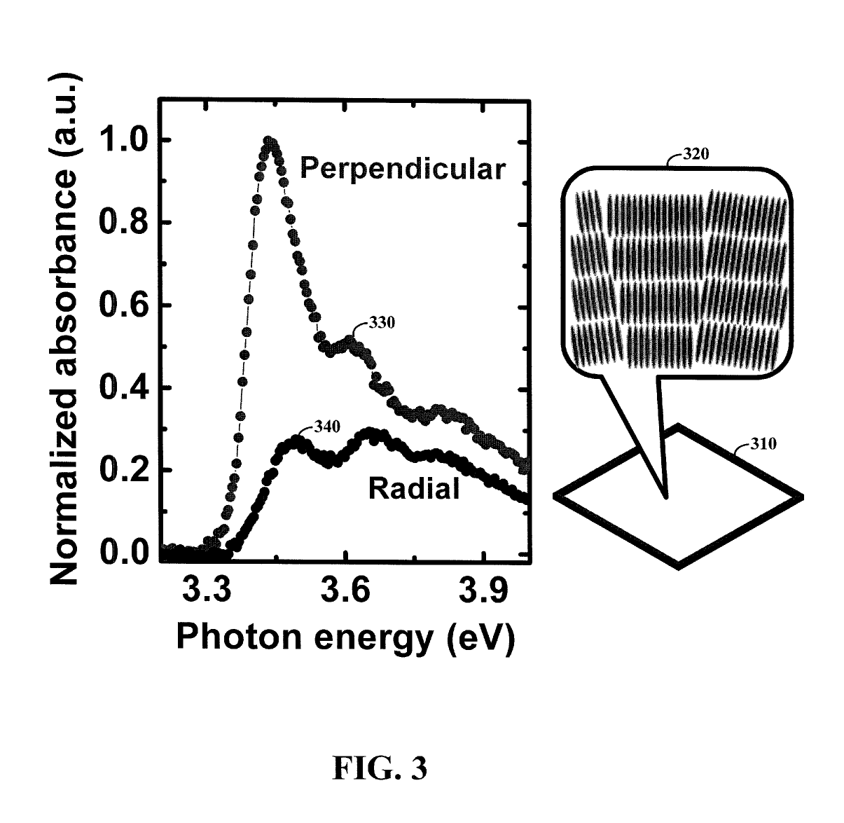

FIG. 3 shows a structure 310 with aligned objects as shown in the inset 320, along with corresponding plots, in accordance with another example embodiment. The objects in the inset 320 are aligned along a direction in which centrifugal force is applied, with relatively unidirectional orientation (e.g., within about 10 degrees of a direction of an applied centrifugal force, such as in the radial direction shown in FIG. 2). The plots show normalized absorbance on the vertical axis and photon energy on the horizontal axis, with plot 330 representing a direction perpendicular to the film and with plot 340 representing a direction radial to the film (relative to spin-coating). The peak absorbance of the C8-BTBT film formed by the OCSC method is about 2.5 times stronger when the light polarization direction is perpendicular to the radial direction as compared to the radial direction. There is a small spectral shift of about 50 meV between peak positions of the first absorption band for the two different polarizations in the OCSC film as plotted, which corresponds to the Davydov splitting of the lowest energy transition in the isolated molecule induced by the anisotropic crystal environment. The C8-BTBT crystals formed by OCSC exhibit a blue shift of about 20 meV in the absorption spectrum onset, with spectral characteristics being indicative of crystal packing of C8-BTBT. Further, a transition dipole moment (TDM) tilt angle (the angle between TDM and the normal direction of a substrate plane) of about 88±3° is provided with various embodiments, consistent with embodiments shown in FIGS. S8, S9 and S10 in Appendix B of the underlying provisional application, and may characterize molecular packing aspects.

As discussed above, off-center spin-coating can be implemented to achieve high mobility films, as noted in embodiments involving C8-BTBT films exhibiting a hole mobility of 43 cm²/Vs for saturation mobility and 20 cm²/Vs for linear mobility. Certain embodiments involve such films reaching saturation mobilities of 90˜118 cm²/Vs. Where implemented in transistor channels, such films exhibit desirably high channel current.

Various apparatuses as described herein may be manufactured in a variety of manners. In particular embodiments, ITO-coated glass substrates or highly doped silicon wafers are used as a base substrate, which is cleaned (e.g., scrubbed with a brush dipped in acetone and subjected to ultrasonic cleaning in pure water, acetone and isopropyl alcohol). These substrates are then dried (e.g., in oven at 80° C.) and treated with ultraviolet (UV)-ozone, and the ITO layer is covered by a low temperature cross-linkable PVP dielectric layer. A cross-linking component such as 4,4′HDA is, with a PVP-HDA layer spin-coated from a 100 mg/ml solution of PVP:HDA (10:1 by wt) in propylene glycol monomethyl ether acetate (PGMEA). The PVP:HDA films are cured (e.g., at 100° C. for 60 minutes) to promote the cross-linking reaction, resulting in a dielectric layer thickness of ˜330 nm and a measured capacitance of 1.2×10⁻⁴ F/m².

Organic semiconductor films are deposited in an nitrogen inert atmosphere on the PVP-HDA-coated ITO substrate from a 5 mg/ml C8-BTBT (or C8-BTBT:PS) solution in DCB via an OCSC method as described herein, with the substrate being placed with its center away from the rotation axis of the spin coater (e.g., a 15×15 mm² substrate placed at a distance of 20-40 mm). During the OCSC process, the spin speed is gradually increased to 2700 rpm. The C8-BTBT crystals are grown gradually from one side to the other side in the radial direction. The C8-BTBT:PS semiconductor layer is fabricated on a PVP surface with a thickness of 10-18 nm, which can be set by changing both spin-coating speed and the solution concentration. Silver (Ag) source and drain electrodes can be thermally evaporated through a silicon shadow mask with a channel length of 100 μm and a channel width of 1 mm, respectively.

Based upon the above discussion and illustrations, those skilled in the art will readily recognize that various modifications and changes may be made to the various embodiments without strictly following the exemplary embodiments and applications illustrated and described herein. For example, one or more aspects of various embodiments described above, in the figures, in the claims or in the underlying provisional application (including the Appendices) may be implemented separately or combined, and different embodiments may be combined as well. Such modifications do not depart from the true spirit and scope of various aspects of the invention, including aspects set forth in the claims.

What is claimed is:

1. A method comprising:
applying solution to a substrate, the solution having objects dispersed therein;
spinning the substrate about an axis that is off-center, relative to a center of the substrate, to align the objects along a predominantly unidirectional orientation; and
solidifying the solution with the objects aligned to one another along the predominantly unidirectional orientation.

2. The method of claim 1, wherein spinning the substrate includes spinning the substrate about an axis that is sufficiently distant from the substrate to apply a centrifugal force to the substrate that is aligned across the substrate.

3. The method of claim 1, wherein solidifying the solution includes forming a predominantly transparent film.

4. The method of claim 3, wherein forming the predominantly transparent film includes forming the film with a mobility sufficient to provide charge carrier flow in response to an electric field.

5. The method of claim 1, wherein applying the solution includes applying a blend including a polymer and an organic semiconductor to the substrate, and wherein spinning the substrate includes aligning molecules of the polymer in the predominantly unidirectional orientation.

6. The method of claim 5, wherein solidifying the blend with the molecules in the predominantly unidirectional orientation includes crystalizing the blend with the crystallization having the unidirectional orientation.

7. The method of claim 1, wherein spinning the substrate includes generating and using centrifugal force to stack the objects in a periodic structure.

8. The method of claim 1, wherein solidifying the solution with the objects in the predominantly unidirectional orientation includes solidifying the solution with objects aligned within about 10 degrees of a direction extending from the axis and through a center of the substrate.

9. The method of claim 1, wherein spinning the substrate includes applying a centrifugal force across the substrate that is about 100 times the force of gravity and thinning the substrate to a thickness of less than about three monolayers of molecules in the solution.

10. The method of claim 1, wherein spinning the substrate includes manipulating the solution, via centrifugal force applied by the spinning, with a thicker region having a meniscus front at an outermost portion of the substrate relative to the axis, and with a thinner region at an innermost portion of the substrate relative to the axis, and wherein solidifying the solution includes initiating solidification of the solution at the innermost portion of the substrate while evaporating solvent from the solution, and propagating a solidification front of the solution from the innermost portion of the substrate toward the outermost portion of the substrate.

11. A spin-coated apparatus comprising:
an organic semiconductor; and
a polymer cooperatively arranged with the organic semiconductor in a film on a substrate, the film having a predominant degree of transparency, and a mobility sufficient to provide charge carrier flow in response to an electric field at the degree of transparency, the polymer being predominantly aligned molecules having a unidirectional crystalline orientation and exhibiting a mobility with the organic semiconductor that is greater than 33 cm²/Vs and less than about 150 cm²/Vs.

12. The apparatus of claim 11, wherein the aligned molecules include an organic polymer blended with polystyrene.

13. The apparatus of claim 11, wherein the aligned molecules exhibit characteristics of a spin-coated film applied with an off-center spin-coating approach about an axis of rotation that is offset relative to the substrate, and that provides the unidirectional crystalline orientation via centrifugal forces aligned across the substrate.

14. The apparatus of claim 13, wherein the film is in a partially-crystallized state in which a portion of the film closest to the axis is solidified, and a portion of the film furthest from the axis is in a liquid state and exhibits a meniscus region having a thickness that is greater than a thickness of the solidified portion of the film, the film having a surface that tapers from the meniscus region to the solidified portion of the film.

15. The apparatus of claim 14, wherein the solidified portion exhibits a concentration gradient set via rapid evaporation of solvent from the film and increased viscosity at the portion of the film closest to the axis as incurred via spin-coating.

16. The apparatus of claim 11, wherein the aligned molecules exhibit characteristics of spin-coated molecules applied with an off-center spin-coating approach that provides the unidirectional alignment via the off-center spin-coating, the film having a surface exhibiting off-center spin-coating characteristics that are different than microflow, concentration gradients, nucleation and crystal growth kinetics exhibited by blade coating of the film.

17. The apparatus of claim 11, wherein the polymer is 2,7-dioctyl[1]benzothieno[3,2-b][1]benzothiophene (C8-BTBT).

18. The apparatus of claim 11, wherein the film is part of a display circuit that displays images through the film, further including an electrode connected to the film and configured and arranged to pass charge via the film for displaying an image.

19. An apparatus comprising:
a spin-coating platform configured and arranged to rotate about an axis;
a substrate on the spin-coating platform and offset from the axis; and
a film on the substrate, the film including objects dispersed therein, the objects being aligned to one another in a predominantly unidirectional orientation that lies along a direction extending from the axis and through the film.

20. The apparatus of claim 19, wherein the spin-coating platform and substrate are configured and arranged with a distance between the axis and the substrate to align the objects along the predominantly unidirectional orientation by imparting a predominantly unidirectional centrifugal force to the film.
